(19) United States
(12) Patent Application Publication
(10) Pub. No.: US 2006/0081905 A1
(43) Pub. Date: Apr. 20, 2006

(54) Dielectric multilayer of microelectronic device and method of fabricating the same

(75) Inventors: Seok-jun Won, Seoul (KR); Dae-jin Kwon, Suwon-si (KR); Jong-ho Lee, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/233,335

(22) Filed: Sep. 22, 2005

(30) Foreign Application Priority Data
Oct. 15, 2004 (KR) 10-2004-0082652

(51) Int. Cl. H01L 29/94

(52) U.S. Cl. 257/310

(57) ABSTRACT

A dielectric multilayer suitable for improving a performance of a microelectronic device and a method of fabricating the dielectric multilayer are provided. The dielectric multilayer of the microelectronic device comprises a composite layer which is formed of oxides of two or more different elements and in which a laminar structure is not formed, and a single layer which is formed on at least one surface of the composite layer and is formed of an oxide of a single element.

This application claims priority from Korean Patent Application No. 10-2004-0082652 filed on Oct. 15, 2004 in the Korean Intellectual Property Office, the contents of which are incorporated herein by reference in their entirety.

### BACKGROUND OF THE INVENTION

1. Field of the Invention

The present invention relates to a dielectric layer of a microelectronic device and a method of fabricating the same, and more particularly, to a dielectric multilayer suitable for improving performance of a microelectronic device and a method of fabricating the dielectric multi layer.

2. Description of the Related Art

Due to advances in highly integrated semiconductor device manufacturing technology, areas occupied by each of a plurality of semiconductor cells have gradually been reduced, without reducing the high operating speed. As the areas occupied by the semiconductor cells have been reduced, horizontal areas for forming transistors and/or capacitors included in each of the cells making up the semiconductor devices have been reduced.

As the lengths of gate electrodes of the transistors are reduced, thicknesses of gate insulating layers are reduced (to about 20 Å or less, for example). Unfortunately, reducing the thicknesses of the gate insulating layers presents several problems such as an increase in a gate leakage current, penetration of gate doping impurities or other impurities, and reduction of a threshold voltage. Thus, research into developing a substitute material having an excellent insulation characteristic and a high dielectric constant for the gate insulating layers has progressed.

Further, cell capacitance has been reduced due to reduction in the formation areas of the capacitors. Accordingly, various technologies which increase cell capacitance without affecting the horizontal areas occupied by the cells have been developed.

To increase capacitance within a limited cell area, a method of reducing the thickness of a dielectric layer of a capacitor and/or a method of increasing an effective area of a capacitor by forming a lower electrode of the capacitor having a three-dimensional structure like a cylinder or a pin, and so on, was proposed. However, it is difficult to obtain a high enough capacitance to operate memory devices using the above methods in fabricating a dynamic random access memory (DRAM) having the integration density required for obtaining a capacity of 1 GB or more.

This leads to consideration of a substitute dielectric layer, which is thicker than the silicon oxide layer which was used as a conventional gate dielectric layer or a dielectric layer of a capacitor, but which still can improve performances of the devices, has been demanded. The performance of can be evaluated and expressed as “equivalent oxide thickness (EOT).”

A physically thicker metal oxide layer can reduce the leakage current without adversely affecting the performance of the devices. Moreover, if the gate dielectric layer can be made sufficiently thick, an etching margin of the gate dielectric layer can be increased during the patterning of a gate electrode. The increase of the etching margin prevents the silicon substrate from being exposed by an etching process for patterning the gate electrode.

For this reason, high-k (high dielectric constant) metal oxides have been suggested as substitutes for the dielectric material that forms the gate dielectric layer or that forms a dielectric layer of a capacitor. Since a dielectric constant of the metal oxide layer is higher than that of the silicon oxide layer, the metal oxide layer, which has an EOT equal to the silicon oxide layer while being physically thicker than the silicon oxide layer, can be used as the gate dielectric layer of a semiconductor device or as the dielectric layer of the capacitor.

### SUMMARY OF THE INVENTION

To solve the above-described problems, the present invention provides a dielectric layer that has a high dielectric constant while showing a stable characteristic in an ambient environment and in subsequent processes.

The present invention also provides a microelectronic device with an improved performance.

The present invention also provides a method of fabricating the dielectric layer and a method of fabricating the microelectronic device.

According to an aspect of the present invention, there is provided a dielectric layer including a composite layer which is formed of oxides of two or more different elements and in which a laminar structure is not formed, and a single layer which is formed on at least one surface of the composite layer and is formed of an oxide of a single element.

According to another aspect of the present invention, there is provided a microelectronic device comprising the dielectric multilayer as a gate dielectric layer, an intergate dielectric layer, or a capacitor interelectrode dielectric layer.

According to yet another aspect of the present invention, there is provided a method of fabricating a dielectric multilayer including forming a composite layer which is formed of oxides of two or more different elements and in which a laminar structure is not formed, and forming a single layer which is formed on at least one surface of the composite layer and is formed of an oxide of a single element.

According to a further aspect of the present invention, there is provided a method of fabricating a microelectronic device including the method of fabricating the dielectric multilayer.

### BRIEF DESCRIPTION OF THE DRAWINGS

The above objects and advantages of the present invention will become more apparent by describing in detail preferred embodiments thereof with reference to the attached drawings in which:

FIG. 1 is a cross-sectional view of a dielectric layer according to a first embodiment of the present invention;

FIG. 2 is a cross-sectional view of a dielectric layer formed of a conventional hafnium oxide layer;

FIG. 3 is a cross-sectional view of a dielectric layer formed by alternately stacking a thin film of conventional hafnium oxide layer and a thin film of aluminum oxide layer;

FIG. 4 is a cross-sectional view of a dielectric layer according to a second embodiment of the present invention;

FIG. 5 is a cross-sectional view of a MOS transistor including a dielectric layer according to the present invention;

FIG. 6 is a cross-sectional view of a flash memory cell transistor including a dielectric layer according to the present invention;

FIG. 7 is a cross-sectional view of a capacitor including a dielectric layer according to the present invention;

FIG. 8 is a flow chart of a fabrication method of the dielectric layer according to the second embodiment of the present invention;

FIG. 9 is a graph showing leakage currents with respect to voltages of a capacitor that includes the dielectric layer according to the second embodiment of the present invention and a capacitor that includes a dielectric layer formed of a conventional hafnium oxide layer; and

FIG. 10 is a graph showing the extent of deterioration of a capacitor that includes the dielectric layer according to the second embodiment of the present invention after treating the capacitor with heat.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

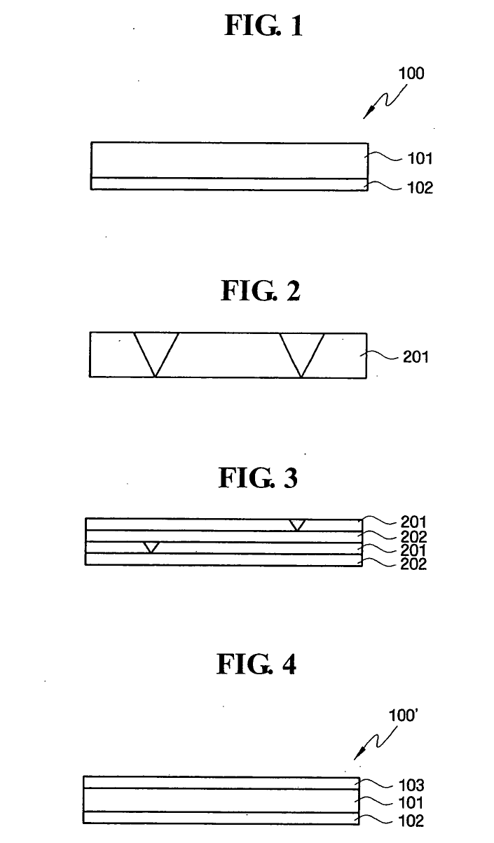

Preferred embodiments of the present invention will be best understood by referring to FIGS. 1 through 8.

FIG. 1 is a cross-sectional view of a dielectric layer according to a first embodiment of the present invention.

A dielectric layer 100 according to the first embodiment of the present invention includes a composite layer 101 and a single layer 102 formed on either surface of the composite layer 101.

The composite layer 101 is formed of oxides of two or more different elements and has a composite structure in which a laminar structure is not formed in the oxides.

As two or more different elements make up the composite layer 101, a high dielectric material which can maximize a dielectric constant of the whole dielectric layer 100 is used. Further, as a material of the composite layer 101, a material which can maintain alignment with the single layer 102 is used. Furthermore, as a material of the composite layer 101, a material which does not react with an upper structure such as a gate electrode, a control gate, and an upper electrode, which can be formed on an upper part of the composite layer 101, and which does not react with a lower structure such as a channel region, a floating gate, and a lower electrode, which can be formed on a lower part of the composite layer 101, can be used. Further, as a material of the composite layer 101, a material which is kept in an amorphous state in a subsequent annealing process for completing a microelectronic device so that a crystal grain boundaries through which current can pass are not formed can be used.

At least one of the oxides of two or more different elements of the composite layer 101 may be formed of a material that is the same or of the same group as an oxide of the single layer 102. In addition, a combination of two or more different oxides can be used so as to minimize net fixed charge in the composite layer 101, which prevents a reduction of channel mobility resulting from Coulomb scattering due to a fixed charge.

An oxide of the composite layer 101 can be expressed by M1ₓM2_{y}O_{z}. Here, M1 and M2 are different, and can be selected among aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y) or manganese (Mn), respectively. Here, values of x and y determining ratios of M1 and M2 are set in the range which has a high dielectric constant and a high crystallization temperature so that an amorphous state can be kept, while the net fixed charge can be minimized or zero.

The composite layer 101 can be formed of an oxide selected among AlₓHf_{y}O_{z}, HfₓSi_{y}O_{z}, HfₓTa_{y}O_{z}, HfₓTi_{y}O_{z}, AlₓTi_{y}O_{z}, ZrₓTa_{y}O_{z}, ZrₓSi_{y}O_{z} or ZrₓTi_{y}O_{z}. The higher a ratio of Hf or Zr of the composite layer 101 is, the greater a dielectric constant of the composite layer 101 is. In this case, however, a crystallization temperature becomes low so that the dielectric layer 100 is crystallized easily, leading to a leakage current. Further, the higher ratios of Ta and Ti of the composite layer 101 are, the greater a dielectric constant of the composite layer 101 is. However, the composite layer 101 is rapidly degraded according to a measured temperature. Accordingly, in a case where the composite layer 101 is formed of a combination the elements, drawbacks due to the low crystallization temperature and the rapid degradation can be overcome.

The composite layer 101 formed of oxides as described above has a composite structure in which a laminar structure is not formed in the oxides.

As shown in FIG. 2, in a particular case where a conventional hafnium oxide layer 201 is formed as a dielectric layer, defects exist in the hafnium oxide layer 201. To reduce such defects, as shown in FIG. 3, the dielectric layer is formed by alternately stacking a thin film of the hafnium oxide layer 201 and a thin film of an aluminum oxide layer 202, thereby making it possible to improve the defects occurring in the hafnium oxide layer 201 to some extent. However, the defects still exist in the thin film of hafnium oxide layer 201, thereby deteriorating a breakdown voltage characteristic.

Accordingly, since the dielectric layer 100 according to the first embodiment of the present invention includes the composite layer having a composite structure in which laminar structures of oxides are not formed, the defects occurring in the hafnium oxide layer 201 can be removed and degradation of breakdown voltage characteristic can be prevented.

The composite layer 101 has a thickness which sufficiently satisfies the above-described characteristics and can maximize a dielectric constant of the whole dielectric layer. Accordingly, a thickness of the composite layer 101 may be 10-500 Å.

The single layer 102 formed on one surface of the composite layer 101 can be formed of an oxide of an element that is physically and chemically more stable than the composite layer 101.

The dielectric layer formed of the conventional hafnium oxide layer 201 as shown in FIGS. 2 and 3 has a high hygroscopic property when exposed to air. In a case where the upper structure or the lower structure on the dielectric layer formed of the hafnium oxide layer 201 is formed of TiN, the dielectric layer reacts highly to TiN. Further, the hafnium oxide layer 201 may be etched by Cl of TiCl₄ used as a precursor of the upper structure or the lower structure formed of TiN.

Accordingly, since the physically and chemically stable single layer 102 is formed on one surface of the composite layer 101 including particularly hafnium oxide in the dielectric layer 100 according to the first embodiment of the present invention, the dielectric layer 100 showing a stable characteristic in an ambient environment and subsequent processes can be obtained.

The single layer 102 is formed of a material which has excellent compatibility with the upper structure such as the gate electrode, the control gate, and the upper electrode, which can be formed on the upper part of the single layer 102, or the lower structure such as the channel region, the floating gate, and the lower electrode which can be formed on the lower part of the single layer 102 and has a low interface trap density (Dit). In addition, the single layer 102 is formed of a material which is kept in an amorphous state in a subsequent annealing process for completing a microelectronic device so that crystal grain boundaries, in which a current can flow, are not formed.

Accordingly, the single layer 102 can be formed of an oxide selected from the group consisting of oxides of aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y) or manganese (Mn). However, the present invention is not limited thereto and any material suitable for the present invention can be used without departing from the spirit and scope of the invention. Particularly, the single layer 102 can be formed of aluminum oxide or silicon oxide.

The single layer 102 has a thickness which sufficiently satisfies the above-described characteristics and can maximize a dielectric constant of the whole dielectric layer. Accordingly, a thickness of the single layer 102 may be 10-500 Å.

FIG. 4 is a cross-sectional view of a dielectric layer according to a second embodiment of the present invention.

A dielectric layer 100′ according to a second embodiment of the present invention includes a composite layer 101 and single layers 102 and 103 respectively formed in both sides of the composite layer 101. The composite layer 101 and two single layers 102 and 103 of the dielectric layer 100′ according to the second embodiment of the present invention have the same structures as those of the composite layer 101 and the single layer 102 of the dielectric layer 100 according to the first embodiment of the present invention. The two single layers 102 and 103 may be formed of an oxide of one element or of oxides of different elements, respectively.

The dielectric layers 100 and 100′ according to the first and second embodiments of the present invention are used in the fabrication of various microelectronic devices. The dielectric layers 100 and 100′ according to the present invention can be used as gate dielectric layers and intergate dielectric layers of a volatile memory device such as DRAM and SRAM or a nonvolatile memory device such as EEPROM and a flash memory device, a micro electro mechanical system (MEMS) device, an optoelectronic device and a display device, or the like, or a dielectric layer of a capacitor. However, these are intended merely to be illustrative.

Further, a possible substrate on which the dielectric layer according to the present invention may be formed is a silicon substrate, a silicon-on-insulator (SOI) substrate, a gallium (Ga)-arsenic (As) substrate, a silicon-germanium (Ge) substrate, a ceramic substrate, a quartz substrate, or the like. However, these are intended merely to be illustrative. Hereinafter, the explanations given will use as an example a silicon substrate, which is most commonly used.

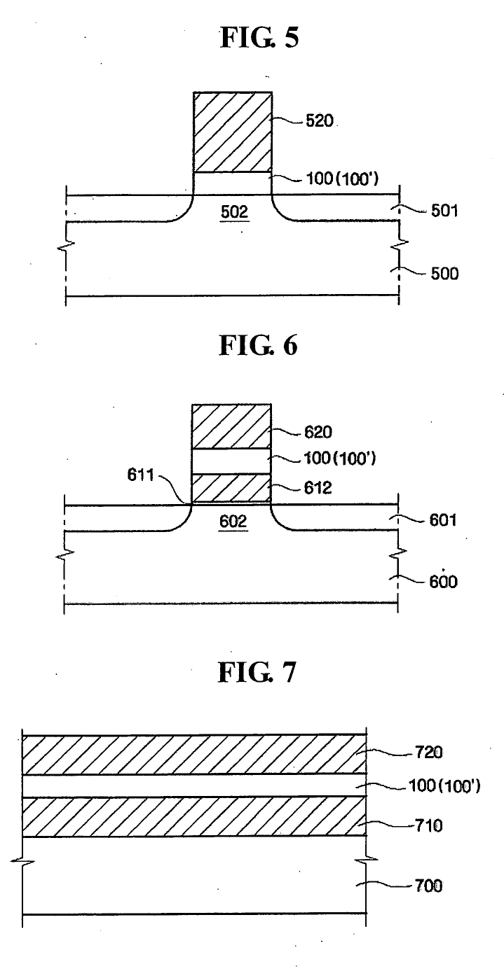

FIGS. 5 through 7 are cross-sectional views of a microelectronic device including the dielectric layer 100 or 100′ according to the present invention. FIG. 5 is a cross-sectional view of a MOS transistor, FIG. 6 is a cross-sectional view of a flash memory cell transistor, and FIG. 7 is a cross-sectional view of a capacitor.

Referring to FIG. 5, the dielectric layer 100 or 100′ according to the present invention is formed on a channel region 502 defined by a source/drain region 501 formed on a silicon substrate 500, and a gate electrode 520 is formed on an upper part of the dielectric layer 100 or 100′. The gate electrode 520 is formed of a polysilicon layer and may be selectively formed in a stacking structure of the polysilicon layer and a silicide layer. Further, the gate electrode 520 may be in the form of a metal gate including a metal. Spacers (not shown) are formed in sidewalls of the dielectric layer 100 or 100′ and the gate electrode 520. Selectively, an oxide layer (SiO₂) (not shown) having a thickness of 4 Å or less, which is naturally formed, may be located on a lower part of the dielectric layer 100 or 100′. Of course, if a process for removing the natural oxide layer is performed, the oxide layer may not be located on a lower part of the dielectric layer 120.

Referring to FIG. 6, a stack of a floating gate 612 and a control gate 620 is formed on a channel region 602 defined by a source/drain region 601 formed on a silicon substrate 600. The dielectric layer 100 or 100′ according to the present invention is formed between the floating gate 612 and the control gate 620. Undefined reference numeral 611 which is not described denotes a gate insulating layer. Although the gate dielectric layer 611 is formed using a conventional dielectric layer, it can be formed using the dielectric layer according to the present invention as in FIG. 5. The control gate 629 is made of a polysilicon layer and may be formed in a stacked structure of the polysilicon layer and a silicide layer. A spacer (not shown) is formed in sidewalls of the control gate 620, the intergate dielectric layer 100 or 100′, the floating gate 612 and the gate dielectric layer 611. Selectively, an oxide layer (SiO₂) (not shown) having a thickness of about 4 Å or less, which is naturally formed, may be further formed on a lower part of the gate dielectric layer 611. Of course, in a case where a process for removing the oxide layer is performed, forming of the oxide layer may be omitted.

Referring to FIG. 7, the dielectric layer 100 or 100′ according to the present invention is formed between an upper electrode 720 and a lower electrode 710 formed on a silicon substrate 700. Here, the lower electrode 710 and the upper electrode 720 may be formed of TiN and the dielectric layer 100 or 100′ may include an aluminum oxide layer formed on at least one surface of the composite layer formed of AlₓHf_{y}O_{z}.

The silicon substrates 500, 600 and 700 of FIGS. 5 to 7 may be a polished silicon substrate and a single crystal epitaxy substrate formed by epitaxial growth, or an SOI substrate. Examples of the capacitor of FIG. 7 include a metal-oxide silicon (MOS) capacitor, a pn-junction capacitor and a polysilicon-insulator-polysilicon (PIP) capacitor.

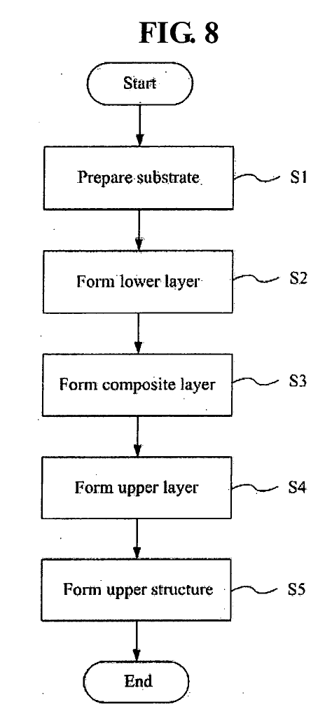

Hereinafter, an explanation will be given of an example of the dielectric layer according to the second embodiment that details a method of fabricating the dielectric layer according to the embodiments of the present invention. FIG. 8 is a flow chart of a fabrication method of the dielectric layer according to the second embodiment of the present invention.

First, the substrates 500, 600 and 700 on which a lower structure, such as the channel region 502, the floating gate 612, and the lower electrode 710 as shown in FIGS. 5 through 7, is formed are prepared in operation S1.

Subsequently, a single layer is formed on the lower structure in operation S2. Hereinafter, the single layer formed on the lower structure is referred to as a lower layer 102.

As described above, the lower layer 102 is formed of an oxide of a single element that is physically and chemically more stable than the composite layer 101 which will be described below.

Although a subsequent thermal process is performed on the lower layer 102 at a high temperature of approximately 900° C., the lower layer 102 is kept in a substantially amorphous state. Thus, there is minimum formation of crystal grain boundaries within the lower layer 102, so that a leakage current can be reduced.

The lower layer 102 can be formed using a deposition method such as chemical vapor deposition (CVD), low pressure CVD (LPCVD), plasma chemical CVD (PECVD) or sputtering. If such methods are used, a thin film is formed at a relatively high temperature. As a result, such methods can cause a thermal effect adversely affecting semiconductor devices.

On the other hand, an atomic layer deposition (ALD) method is performed at a lower temperature compared with the CVD method so that the thermal effect is reduced and uniformity is improved. Accordingly, in fabricating the dielectric layer 100′ according to the second embodiment of the present invention, the lower layer 102 can be formed using the ALD method. By forming the lower layer 102 using the ALD method, various precursors can be used and the thicknesses of layers and compositions of oxides can be controlled precisely.

The ALD method for forming the lower layer 102 can be carried out by performing supply processes of a metal or nonmetal source, a purge gas, and an oxygen source alternately with supply processes of the purge gas, repeatedly. The lower layer 102 is formed to a thickness of 1-50 Å by repeatedly performing the above processes.

As the metal or nonmetal source, a material including any one among aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y) or manganese (Mn) can be used.

As the oxygen source, H₂O, O₃, O radical, alcohol (for example, isopropyl alcohol), D₂O, H₂O₂, O₂, N₂O, NO can be used. In addition, other precursors suitable for the present invention can be used without departing from the spirit and scope of the present invention.

Selectively, before forming the lower layer 102, a process for removing an oxide layer (SiO₂) (not shown) of a thickness of several Å or less which is naturally formed on the substrates 500, 600 and 700 may be added.

Subsequently, a composite layer 101 is formed on the single layer, i.e., the lower layer 102, in operation S3.

If the composite layer 101 is formed of oxides of two or more different elements, the dielectric constant of the whole dielectric layer 100 or 100′ can be increased, thereby making it possible to reduce equivalent oxide thickness (EOT). Particularly, if the composite layer 101 is formed of oxides including a metal or nonmetal that is the same as or of the same group as that of the lower layer 102, an electrical characteristic of the composite layer 101 is compatible with that of the lower layer 102, thereby making it possible to complete a dielectric layer having a more stable structure. Further, if the composite layer 101 is formed of oxides of a combination of a metal or nonmetal having two or more different elements, enabling minimization of the total amount of net fixed charge in the composite layer 101, a reduction of channel mobility resulting from Coulomb scattering due to a fixed charge can be effectively prevented. Further, since formation heat using a combination of a metal or nonmetal having two or more different elements is lower than formation heat using a single metal or nonmetal, it is possible to make the composite layer 101 kept in an amorphous state.

The ALD method for forming the composite layer 101 including oxides of two or more different elements is comprised of an A process cycle including supply processes of a metal or a nonmetal (M1) source, a purge gas, and an oxygen source, alternating with supply processes of the purge gas, and a B process cycle including supply processes of a metal or a nonmetal (M2) source different from that of the above A process, a purge gas, and an oxygen source, alternating with supply processes of the purge gas. The A process cycle is repeated m times and then the B process cycle is repeated n times, thereby performing the ALD method for forming the composite layer 101 in the range in which a laminar structure is not formed. Further, conditions for forming the composite layer 101 are determined by considering whether the composite layer 101 can be formed in an amorphous state due to a high crystallization temperature of the formed material, whether net fixed charge can be minimized, and whether a dielectric constant can be maximized. Particularly, values of m and n of the A process cycle and the B process cycle may be in the range of 1-10, so that the laminar structure is not formed. It is a matter of course that the values of m and n can be set to various values by those skilled in the art.

In a case where the composite layer 101 is formed of HfₓAl_{y}O_{z}, the higher a ratio of Hf is, the higher a dielectric constant of the composite layer 101 is. However, a crystallization temperature of the composite layer 101 decreases gradually. In a case where Hf and Al are used as M1 and M2, respectively, when the ALD method is performed on condition that a ratio of an Hf process cycle to an Al process cycle is 4:1, that is, an A-A-A-A-B process cycle is carried out, a laminar structure is not formed in the composite layer 101. Thus, since defects generated in a conventional HfO₂ layer are suppressed, the occurrence of a leakage current can be reduced. A dielectric constant of the composite layer 101 formed by the process cycle as described above is 15 or greater. More preferably, the composite layer 101 can have a dielectric constant of 20 or greater and a crystallization temperature of 850-900° C. or higher. Further, in a case where a ratio of an Hf process cycle to an Al process cycle is 4:1, a dielectric layer in which net fixed charge is almost 0 can be formed. This is based on the fact that an Al₂O₃ layer has negative fixed charge, an HfO₂ layer has positive fixed charge, and the positive fixed charge in the HfO₂ layer is half of the negative fixed charge in an Al₂O₃ layer that has the same thickness as the HfO₂ layer. Such fact is disclosed fully in U.S. Patent Publication No. 2002/0106536 which is commonly owned by the same assignee and is incorporated herein by reference in its entirety as fully disclosed in the present invention.

Specifically, a Hf process cycle, in which a Hf (e.g., HfCl₄) source, a purge gas, an oxygen source, and a purge gas are supplied in that order, is repeated 4 times, and then an Al process cycle, in which an Al source, a purge gas, an oxygen source, and a purge gas are supplied in that order, is performed once, thereby forming an HfₓAl_{y}O_{z}, layer having a thickness of 10-500 Å. Here, a laminar structure must not be formed in the HfₓAl_{y}O_{z} layer. As the Hf source, HfCl₄, Hf(OtC₄H₉)₄, Hf(OC₂H₅)₄, Hf(N(C₂H₅)₂)₄, Hf(N(CH₃)₂)₄, and Hf(dmae)₄ (dmae is dimethylamine) can be used and tetramethylaluminum (TMA) can be used as the Al source.

As described above, in a case where a repeating ratio of the Hf process cycle to the Al process cycle is fixed, composition ratios of Hf and Al are uniform.

However, when occasion demands, a repeating ratio of the Hf process cycle to the Al process cycle is changed so that a dielectric layer having a gradation in the concentration distribution can be formed. For example, in a case where the lower layer 102 and an upper layer which will be described are formed of aluminum oxide, a ratio of aluminum is high in a region where the composite layer 101 makes contact with the lower layer 102 and the upper layer, thereby making it possible to improve compatibility of the composite layer 101 with the lower layer 102 and the upper layer.

A single layer is continually formed on the composite layer 101 in operation S4. Hereinafter, the single layer formed on top of the composite layer is referred to as an upper layer 103.

As described above, the upper layer 103 is formed of an oxide of a single element that is physically and chemically more stable than the composite layer 101.

Further, although a subsequent thermal process is performed on the upper layer 103 at a high temperature of 900° C., the upper layer 103 is kept in a substantially amorphous state. Thus, there is minimum formation of crystal grain boundaries within the upper layer 103, so that a leakage current can be reduced.

The upper layer 103 can be formed using a deposition method such as chemical vapor deposition (CVD), low pressure CVD (LPCVD), plasma chemical CVD (PECVD) or sputtering. If such methods are used, a thin film is formed at a relatively high temperature. As a result, such methods can cause a thermal effect adversely affecting semiconductor devices.

On the other hand, an atomic layer deposition (ALD) method is performed at a lower temperature compared with the CVD method so that the thermal effect is reduced and uniformity is improved. Accordingly, in fabricating the dielectric layer 100′ according to the second embodiment of the present invention, the lower layer 102 can be formed using the ALD method. By forming the lower layer 102 using the ALD method, various precursors can be used and the thicknesses of layers and compositions of oxides can be controlled precisely.

The ALD method for forming the upper layer 103 can be carried out by performing supply processes of a metal or nonmetal source, a purge gas, and an oxygen source alternately with supply processes of the purge gas, repeatedly. The upper layer 103 is formed to a thickness of 1-50 Å by repeatedly performing the above processes.

As the metal or nonmetal source, a material including any one among aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y) or manganese (Mn) can be used.

As the oxygen source, H₂O, O₃, O radical, alcohol (for example, isopropyl alcohol), D₂O, H₂O₂, O₂, N₂O, NO can be used. In addition, other precursors suitable for the present invention can be used without departing from the spirit and scope of the present invention.

Finally, an upper structure is formed in operation S5.

An upper structure such as the gate electrode 520, the control gate 620, and the upper electrode 720 is formed on a resultant structure in which the upper layer 103 is formed. In a case where the dielectric layer according to the present invention is formed, there is an advantage in that the upper structure can be formed using polysilicon which is widely used in a conventional process in mass production.

The dielectric layer fabricated by the fabrication method as described above includes the composite layer 101 in which the laminar structure is not formed, so that the defects occurring in the middle of a conventional hafnium oxide layer do not exist, thereby making it possible to improve leakage current characteristics.

Further, hafnium oxide existing on the composite layer 101 is prevented from being directly exposed to the air by the lower layer 102 and the upper layer 103, which are located on opposing surface of the composite layer 101 and which are formed of an oxide of a material that is physically and chemically more stable than the composite layer 101, so that a problem occurring by a hygroscopic property can be solved. Furthermore, since hafnium oxide existing on the composite layer 101 directly contacts the upper structure or the lower structure, hafnium oxide does not react with components included in the upper structure or the lower structure and the composite layer 101 is not etched.

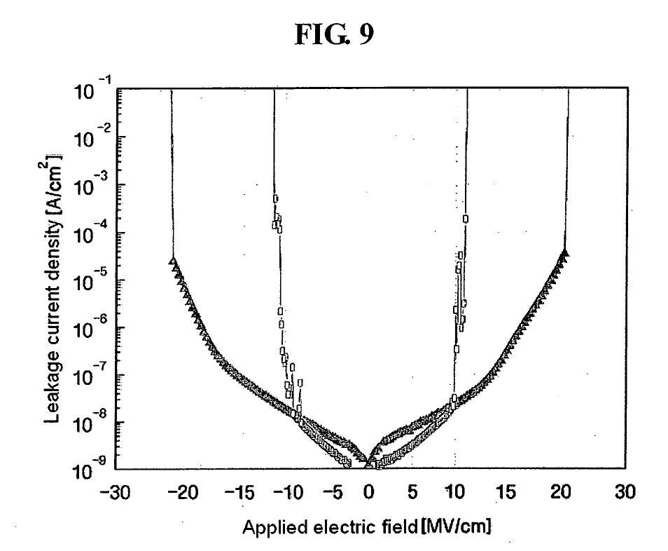

FIG. 9 is a graph showing leakage currents with respect to voltages of a capacitor which includes the dielectric layer fabricated by the above fabrication method and is comprised of a lower electrode (TiN)-a dielectric layer (Al₂O₃/HfₓAl_{y}O_{z}/Al₂O₃)-an upper electrode (TiN), and a capacitor which includes upper and lower electrodes the same as those of the above capacitor and a dielectric layer formed of a conventional hafnium oxide layer. It can be seen that an initial leakage current is low; however, a breakdown voltage occurs at a low current in the capacitor (□) including the conventional dielectric layer. As compared with the above capacitor, it can be seen that a leakage current is greatly improved in the capacitor (▴) including the dielectric layer according to the present invention.

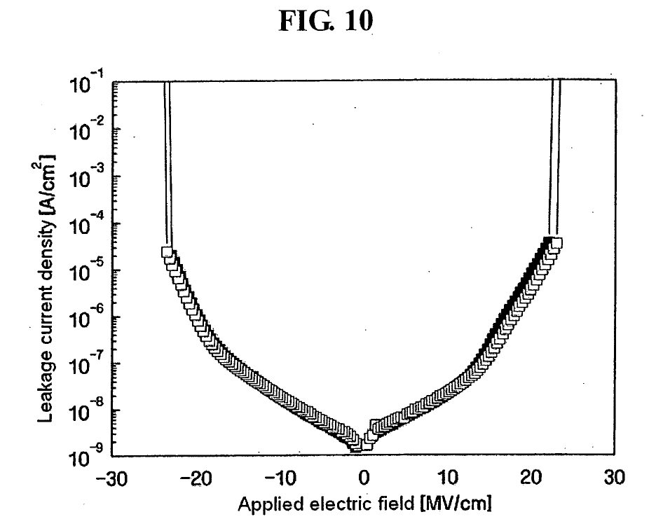

FIG. 10 is a graph showing the extent of deterioration of a capacitor including the dielectric layer according to the present invention after treating the capacitor with heat. Referring to FIG. 10, when a case (□), where the dielectric layer according to the present invention is treated with H₂-heat at a temperature of 400° C. for 30 minutes, is compared with a case (▪), where the dielectric layer is not treated with heat, it can be seen that the deterioration of the capacitor does not occur in the case (□).

As described above, according to the present invention, leakage current characteristics are improved by using a dielectric layer, including a composite layer having a high dielectric constant and a single layer formed of a physically and chemically stable oxide. Further, a stable characteristic of the dielectric layer is maintained in an ambient environment and subsequent processes so that a dielectric constant of the whole dielectric layer can be maximized. As a result, a performance of a microelectronic device including the above dielectric layer can be improved.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A dielectric multilayer comprising:
a composite layer which is formed of oxides of two or more different elements and in which a laminar structure is not formed; and
a single layer which is formed on at least one surface of the composite layer and is formed of an oxide of a single element.

2. The dielectric multilayer of claim 1, wherein the composite layer is formed of an oxide expressed by M1ₓM2_{y}O_{z}.

3. The dielectric multilayer of claim 2, wherein M1 and M2 are different and are selected from the group consisting of aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y) and manganese (Mn).

4. The dielectric multilayer of claim 2, wherein the composite layer is formed of an oxide selected from the group consisting of AlₓHf_{y}O_{z}, HfₓSi_{y}O_{z}, HfₓTa_{y}O_{z}, HfₓTi_{y}O_{z}, AlₓTi_{y}O_{z}, ZrₓTa_{y}O_{z}, ZrₓSi_{y}O_{z} and ZrₓTi_{y}O_{z}.

5. The dielectric multilayer of claim 1, wherein the single layer is formed of an oxide selected from the group consisting of oxides of aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y) and manganese (Mn).

6. The dielectric multilayer of claim 1, wherein in a case where the single layers are formed on opposing surfaces of the composite layer, respectively, the single layers are formed of an oxide of the same element, respectively.

7. The dielectric multilayer of claim 1, wherein in a case where the single layers are formed on opposing surfaces of the composite layer, respectively, the single layers are formed of oxides of different elements, respectively.

8. The dielectric multilayer of claim 1, wherein the single layer is formed of aluminum oxide or silicon oxide.

9. A microelectronic device comprising a dielectric multilayer, comprising a composite layer which is formed of oxides of two or more different elements and in which a laminar structure is not formed; and a single layer which is formed on at least one surface of the composite layer and is formed of an oxide of a single element, as a gate dielectric layer.

10. A microelectronic device comprising a dielectric multilayer, comprising a composite layer which is formed of oxides of two or more different elements and in which a laminar structure is not formed; and a single layer which is formed on at least one surface of the composite layer and is formed of an oxide of a single element, as an intergate dielectric layer.

11. A microelectronic device comprising a dielectric multilayer, comprising a composite layer which is formed of oxides of two or more different elements and in which a laminar structure is not formed; and a single layer which is formed on at least one surface of the composite layer and is formed of an oxide of a single element, as a capacitor interelectrode dielectric layer.

12. A capacitor comprising:
a lower electrode;
a dielectric multilayer including a composite layer which is formed on the lower electrode and is formed of AlₓHf_{y}O_{z}, and aluminum oxide layers formed on upper and lower parts of the composite layer; and
an upper electrode formed on the dielectric multilayer.

13. The capacitor of claim 12, wherein the composite layer, in which a laminar structure is not formed, is formed of AlₓHf_{y}O_{z} using an atomic layer deposition (ALD) method which performs a process cycle including a supply process of an aluminum source, a supply process of a purge gas and a supply process of an oxygen source 1 time and then repeatedly performs a process cycle including a supply process of a hafnium source, a supply process of a purge gas and a supply process of an oxygen source 4 times.

14. The capacitor of claim 12, wherein the lower electrode and the upper electrode are formed of TiN.

15. A method of fabricating a dielectric multilayer comprising:
forming a composite layer which is formed of oxides of two or more different elements and in which a laminar structure is not formed; and
forming a single layer which is formed on at least one surface of the composite layer and is formed of an oxide of a single element.

16. The method of claim 15, wherein the composite layer is formed of an oxide expressed by M1ₓM2_{y}O_{z}.

17. The method of claim 16, wherein M1 and M2 are different and are selected from the group consisting of aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y), and manganese (Mn).

18. The method of claim 16, wherein the composite layer is formed of an oxide selected from the group consisting of AlₓHf_{y}O_{z}, HfₓSi_{y}O_{z}, HfₓTa_{y}O_{z}, HfₓTi_{y}O_{z}, AlₓTi_{y}O_{z}, ZrₓTa_{y}O_{z}, ZrₓSi_{y}O_{z} or ZrₓTi_{y}O_{z}.

19. The method of claim 16, wherein the composite layer is formed using an ALD method comprised of an A process cycle including a supply process of an M1 source, a supply process of a purge gas, and a supply process of an oxygen source, alternating with a supply process of a purge gas, and a B process cycle including a supply process of an M2 source, a supply process of a purge gas, and a supply process of an oxygen source, alternating with a supply process of a purge gas;
wherein the A process cycle is repeated m times and then the B process cycle is repeated n times, thereby forming the composite layer in which a laminar structure is not formed.

20. The method of claim 19, wherein m and n are in the range of 1-10.

21. The method of claim 15, wherein the single layer is formed of an oxide selected from the group consisting of oxides of aluminum (Al), hafnium (Hf), zirconium (Zr), lanthanum (La), silicon (Si), tantalum (Ta), strontium (Sr), barium (Ba), lead (Pb), chromium (Cr), molybdenum (Mo), tungsten (W), titanium (Ti), yttrium (Y) and manganese (Mn).

22. The method of claim 15, wherein in a case where the single layers are formed on opposing surfaces of the composite layer, respectively, the single layers are formed of an oxide of the same element, respectively.

23. The method of claim 15, wherein in a case where the single layers are formed on opposing surfaces of the composite layer, respectively, the single layers are formed of oxides of different elements, respectively.

24. The method of claim 15, wherein the single layer is formed of aluminum oxide or silicon oxide.

25. A method of fabricating a microelectronic device having a dielectric multilayer as a gate dielectric layer, the dielectric multilayer fabricated by a method comprising forming a composite layer which is formed of oxides of two or more different elements and in which a laminar structure is not formed, and forming a single layer which is formed on at least one surface of the composite layer and is formed of an oxide of a single element.

26. A method of fabricating a microelectronic device having a dielectric multilayer as an intergate dielectric layer, the dielectric multilayer fabricated by a method comprising forming a composite layer which is formed of oxides of two or more different elements and in which a laminar structure is not formed, and forming a single layer which is formed on at least one surface of the composite layer and is formed of an oxide of a single element.

27. A method of fabricating a microelectronic device having a dielectric multilayer as a capacitor interelectrode dielectric layer, the dielectric multilayer fabricated by a method comprising forming a composite layer which is formed of oxides of two or more different elements and in which a laminar structure is not formed, and forming a single layer which is formed on at least one surface of the composite layer and is formed of an oxide of a single element.

28. A method of fabricating a capacitor comprising:
forming a lower electrode;
forming a dielectric multilayer including a composite layer which is formed on the lower electrode and is formed of AlₓHf_{y}O_{z} and aluminum oxide layers formed on upper and lower parts of the composite layer; and
forming an upper electrode on the dielectric multilayer.

29. The method of claim 28, wherein the composite layer, in which a laminar structure is not formed, is formed of AlₓHf_{y}O_{z} using an atomic layer deposition (ALD) method which performs a process cycle including a supply process of an aluminum source, a supply process of a purge gas and a supply process of an oxygen source 1 time and then repeatedly performs a process cycle including a supply process of a hafnium source, a supply process of a purge gas and a supply process of an oxygen source 4 times.

30. The method of claim 28, wherein the lower electrode and the upper electrode are formed of TiN.
